(19) United States
(12) Patent Application Publication
(10) Pub. No.: US 2006/0145776 A1
(43) Pub. Date: Jul. 6, 2006

(54) High-speed VCO calibration technique for frequency synthesizers

(76) Inventors: Qian Shi, San Diego, CA (US); Kevin Hsi-Huai Wang, San Diego, CA (US)

Correspondence Address: HungChang Lin, 8 Schndler Ct., Silver Spring, MD, 20903, US

(21) Appl. No.: 11/028,693

(22) Filed: Jan. 5, 2005

(51) Int. Cl. H03L 1/00

(52) U.S. Cl. 331/175

(57) ABSTRACT

The voltage-controlled oscillator (VCO) in a frequency synthesizer using a phase-locked loop (PLL) is calibrated digitally during power up. The VCO has a coarse frequency control and a fine frequency control. The coarse control is a digital phase-locked loop to quantize the broad frequency range into limited number of frequency steps with a clock frequency divided from the VCO frequency, and to hold the phase-locked dc control voltage for the fine control. By limiting the number of frequency steps and clocking at a divided frequency of the VCO, the coarse control is speeded up. The fine control is [connected to the charge pump output as in] a regular PLL. By searching for the optimal control setting, the center frequency of the VCO is trimmed close to the wanted frequency for the PLL to lock. This allows small VCO gain without losing the tolerance of process and temperature variations. As a result, the PLL phase noise performance is improved.

### BACKGROUND OF THE INVENTION

1. Field of the Invention

This invention is to greatly reduce the calibration time of a low phase noise voltage-controlled oscillator (VCO) within an integrated radio transceivers, particularly the low-power consumption is the key requirement.

2. Brief Description of Related Art

In integrated radio transceivers, VCO is used to generate RF frequency for use in frequency synthesizers. Process and temperature variations usually cause large deviation to VCO free-running center frequency. Welland, proposed in U.S. Pat. No. 6,137,372, used both coarse and fine tuning arrangement to VCO. The coarse tuning, also mentioned as calibration, brings VCO center frequency to desired frequency, by using digital words. And the fine tuning is the traditional way for voltage-control as any other type of VCOs. A wider coarse tuning range means a narrower fine tuning range. This has reportedly helped to improve VCO phase noise. However, the speed for the calibration is constantly a major concern in modern integrated radio transceiver design. Many efforts have been made to achieve wide coarse tuning range with a reasonable calibration time.

Chien proposed, in U.S. Pat. No. 6,597,249, a binary search algorithm to find the optimal digital control word. The binary search algorithm greatly reduces the search time compared to a linear search algorithm.

Dai et al. proposed in U.S. patent application Ser. No. 10/687,492 a search-with-averaging algorithm to further speed up the calibration process. However, Dai's patent application still leaves ground for improvement in terms of speed and phase noise.

### SUMMARY OF THE INVENTION

An object of this invention is to further shorten VCO calibration time while maintaining the coarse tuning range the same as described in U.S. patent application Ser. No. 10/687,492. In other words, if one uses the same length of calibration time as previous work, the present invention can obtain wider coarse-tuning range. The importance is two fold. First, a shorter calibration time means a shorter settling time of a frequency synthesizer. This feature is very useful in two aspects. It saves power of synthesizer because power-on to settle-down time is shorter; and it supports calibration during channel switching time, not only at power-on time. Secondly, a narrower fine-tuning range means a better VCO phase noise performance.

The object is achieved by first using a very fast calibration loop of the VCO. The calibration loop is a digital phase-locked loop, which quantizes the coarse tuning varactor capacitance for the VCO to yield discrete number of steps corresponding to different frequency ranges. The clock frequency for the frequency stepper of the calibration loop is divided from the VCO frequency. It is then used to count a reference frequency. If the calibration clock frequency is much higher than the reference frequency, the speed of the calibration loop to lock depends on the reference frequency and the steps to count. The clock frequency varies with the VCO frequency. If the clock frequency to the reference frequency is preset, calibration terminates when the clock frequency equals to the product of the reference clock frequency and the preset ratio. In this way, the VCO, from which the clock frequency is divided, has been insured to run at the wanted frequency. The maximum time needed for calibration is the product of time for each step and the number of steps. The time for each step is equal to one reference frequency period. For instance, if there are 32 steps, the calibration clock is divided by 16 from a 1.668 GHz VCO frequency to be 104.25 MHz, and the reference frequency is 800 KHz or 1.25 μS period, then the calibration time is at most 40 μS, provided the VCO has settled in each step. Assuming that the VCO needs about 200 nS to settle in each step, then the total time does not exceed 50 μS. If 1.668 GHz is the wanted VCO frequency, then the preset ratio is 130. Calibration terminates at such a step that the coarse tuning varactor capacitance can adjust the resonant tank to yield a 1.668 GHz VCO frequency. If allowable digital quantization error is +/−1 Least Significant Bit (LSB), then the VCO frequency is around 1.668 GHz within +/−1 LSB error. 1LSB error is calibrated from the estimated total VCO frequency variation due to process and temperature variation. For example, +/−150 MHz variation for a 32 stepper results in 1 LSB of +/−4.7 MHz. The calibration frequency for the calibration loop is normally divided from a crystal oscillator frequency. The crystal frequency is also divided to generate phase comparison frequency for synthesizer. The calibration reference frequency and the synthesizer phase comparison frequency do not have to be equal. The analog control voltage for the VCO is preset to a middle value before calibration starts. After calibration, the calibration loop is broken, and the VCO is switched back to the analog synthesizer loop. The count and the control voltage are held to initiate the analog synthesizer loop. The count is held in a register until next calibration is initiated, but the control voltage is set free for fine tuning until next calibration is initiated. As can be seen from the foregoing description by using a variable fast clock which corresponds to the VCO frequency to count a fixed relatively slow reference frequency, a much faster calibration time than prior art can be achieved.

### BRIEF DESCRIPTION OF THE DRAWINGS

Table 1 shows the pin description.

FIG. 1 shows a block diagram of a phase-locked loop (PLL)

FIG. 2 shows a calibration circuit for a PLL based on the present invention.

FIG. 3 shows a block diagram of the VCO calibration circuit.

FIG. 4 shows state transition diagram of CNT.

FIG. 5 shows state transition diagram of DCSN.

FIG. 6 shows the case where VCO is too slow.

FIG. 7 shows the case where VCO is too fast.

FIG. 8 shows the case where VCO frequency is right at the desired one (1.668 GHz in this example).

### DETAILED DESCRIPTION OF THE INVENTION

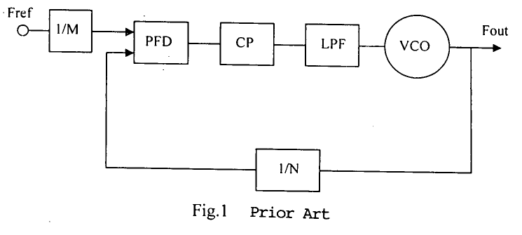

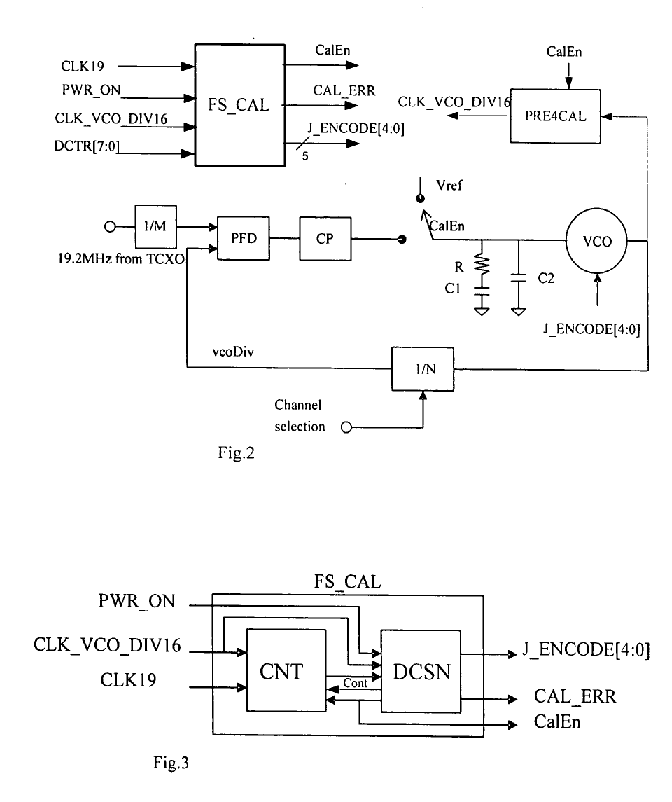

The synthesizer of the present invention operates with two sequential modes; a digital calibration mode and an analog mode. Consequently, the synthesizer can form two individual loops corresponding to the two different modes. During the calibration mode, the synthesizer switches to the calibration loop. The synthesizer locks the frequency of a VCO coarsely but rapidly to the reference frequency by generating an approximate control voltage for the VCO and to set the VCO frequency within a certain tolerance. This approximate control voltage is used to initiate operating a conventional phase-locked loop in the analog mode for fine tuning of the VCO. The calibration circuit with the PLL is drawn in FIG. 2. The calibration PLL uses a FS_CAL block shown in FIG. 3, as a coarse phase detector instead of the conventional phase-comparator. charge-pump, PFD+CP phase detector shown in FIG. 1. The calibration is triggered by a rising edge of PWR_ON signal to FS_CAL block. It first breaks the conventional PLL loop by raising CalEn signal to the FS_CAL block. The VCO control input is switched to a fixed voltage Vref. Vref is used in calibration mode as a fixed control voltage, because VCO must have a control voltage in operation. The value of Vref is set to the middle of the allowable VCO control voltage range. For example, if in PLL shown in FIG. 2 the VCO control voltage range is from 0.5V to 2.5V, Vref can be set to 1.5V. The frequency of the free-running VCO is divided by 16 by a prescaler block PRE4CAL to a frequency about 104.25 MHz. The divided frequency is then fed back to the FS_CAL phase detector through CLK_VCO_DIV16 pin. The divided frequency is then used as a fast variable clock to measure a slow but fixed-period 800 KHz that is divided from the CLK19. FS_CAL block makes decision after each measurement is done and sends the decision to VCO coarse tuning capacitor bank, which is not shown through a 5 bit digital word J_ENCODE[4:0]. The bank serves as a variable varactor, working with the fine tuning varactor and the tank inductor to define the VCO LC tank resonance frequency, J_ENCODE[4:0] has 5 bits which corresponds to 32 discrete levels. The allowable J_ENCODE[4:0] is from decimal 0 to 31. These 5 bits are first sent to a thermometer decoder. The 32 thermometer-coded digital bits are then sent to 32 switches in the coarse-tuning vavactor bank. These switches can then switch on or off those varactors t combine a total varactor capacitance. The varactor bank is realized by accumulative MOS varactor with its gates biased at middle of supply voltage. The switching logic for the varactor bank total capacitance is preset to reduce the total capacitance with increasing J_ENCODE [4:0]. Therefore the VCO frequency increases with increasing J_ENCODE[4:0] digital number with a fixed VCO control voltage. When a satisfied measurement result is obtained, FS_CAL block fixes the J_ENCODE[4:0] values in registers, resets CalEn to 0, and the analog PLL loop, including a phase comparator and a charge pump phase detector, is closed. The loop is then switched from digital calibration mode into analog mode, following by the settling of a conventional PLL.

The nominal VCO frequency at room temperature is a function of its analog control voltage for each incremental value of J_ENCODE[4:0]. It varies over process and temperature. The output frequency of the feedback divider, which divides the VCO frequency by N times, also varies over process and temperature. By setting the correct value of J_ENCODE[4:0], the divider output frequency is trimmed to its closest value of 300 KHz, which is the phase comparison frequency, or the target frequency for phase locking. For a fixed control voltage, the frequency resolution at the divider output is within +/−1 KHz for a single LSB step of J_ENCODE[4:0] in this case, provided that 1LSB error form calibration being +/−4.7 MHz and N being 1.668 GHz/300 KHz=5560.

The block diagram of the calibration circuit is shown in FIG. 2. It includes an 8-bit counter CNT and a decision making block DCSN. The I/O pins are described in Table 1. CNT counts the fast clock CLK_VCO_DIV16, and indicates whether to incrementally change or to keep J_ENCODE[4:0]. DCSN is a control unit that enables or disables CNT through CalEn, and calculates the VCO control value J_ENCODE[4:0]. CalEn signal also breaks or reconnects the PLL loop. To simplify the control logic, J_ENCODE[4:0] is set to decimal 0 in the beginning of every calibration mode. The calibration is finished when the CNT indicates to hold the calibrated J_ENCODE[4:0] value in stead of incrementally changing the J_ENCODE[4:0].

TABLE 1
Pin descriptions

| Pin | I/O | Description |
|---|---|---|
| PWR_ON | I | Rising edge triggers the start of the |
| | | calibration. Falling edge enable CalEn. |
| CLK_VCO_DIV16 | I | PRE4CAL output, frequency is VCO |
| | | frequency divided by 16; |
| CLK19 | I | 19.2 MHz clock from TCXO |
| J_ENCODE[4:0] | O | VCO frequency control, “00000”: lowest |
| | | frequency, “11111”: highest frequency; |
| | | default: “00000” |
| Cont | N/A | ‘1’: CNT works; ‘0’: CNT waits; |
| | | default: ‘0’ |
| CAL_ERR | O | ‘1’: VCO calibrated with error; ‘0’: VCO |
| | | calibrated without error; default: ‘0’ |
| CalEn | O | ‘1’: enables CNT, DCSN, PRE4CAL, puts |
| | | PLL into calibration mode; ‘0’: disables |
| | | CNT, DCSN, PRE4CAL, puts PLL into |
| | | analog mode; default: ‘0’ |

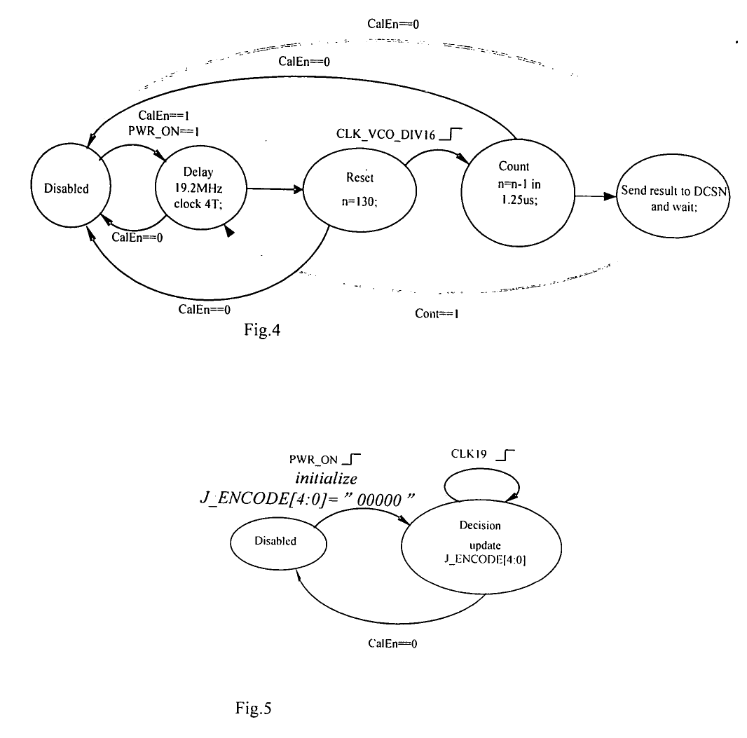

CNT and DCSN are state machines whose state transition diagrams are shown in FIG. 4 and FIG. 5. At the end of the calibration, the calibration result should be held at J_ENCODE[4:0], and the signal CalEn should be held low, indicating the end of the calibration. CalEn will be brought up to high again at the falling edge of the signal PWR_ON. The calibration starts again at the next rising edge of the signal PWR_ON. CAL_ERR is an indicating signal after calibration is set low if the calibration is successful. Otherwise, it is set high indicating an error in VCO calibration.

PRE4CAL and CNT are powered up when CalEn is high. First CNT waits for about 200 ns. This allows enough time for the VCO frequency to settle. Then it starts to count for every cycle of CLK_VCO_DIV16 in 1.25 us, which is the period of the 800 KHz slow clock. At the beginning of the calibration mode, the default value of J_ENCODE[4:0] in the registers is set to decimal 0 by DCSN. The count result is the number of cycles of VCO_CLK_DIV16 in 1.25 us time interval. It is saved in the first group of registers as decimal number, say, M1. If M1 is more than 130, it indicates that the VCO is too fast to be able to calibrate. In this case, DCSN writes CAL_ERR to high, CalEn to low, thus the calibration stops. When M1 is less than 130, M1 is saved in the first group of registers. DCSN then increases J_ENCODE[4:0] by decimal 1. The VCO frequency is then increased by about 10 MHz. CNT waits for 200 ns for VCO to settle and counts VCO_CLK_DIV16 again in 1.25 us time interval. When the count is done, M1 is shifted to the second group of registers as M2, and the new counted result is saved as M1. If M1 is still less than 130, DCSN increases J_ENCODE[4:0] by decimal 1 again, and repeats the iterations. During the iteration, if M1 becomes more than 130, it is a critical time for DCSN. DCSN now compares M1 and M2 to pick the one which is closer to 130. If M1 is closer to 130, or M1 and M2 are equally close to 130, DCSN keeps the J_ENCODE[4:0] and writes CalEn to low. If M2 is closer to 130, DCSN reduces J_ENCODE[4:0] value by decimal 1, and writes CalEn to low. The J_ENCODE[4:0] value is stored in registers until next calibration mode comes, thus the calibration stops. If M1 and M2 keep increasing until J_ENCODE[4:0] is bigger than 31, DCSN writes CAL_ERR to high and CalEn to low to indicate an error then stops the calibration, indicating the VCO is too slow to be able to calibrate.

The falling edge of signal PWR_ON sets CalEn to high, which activates the counter CNT, breaks the analog PLL loop, and sets the VCO control voltage to Vref. The decision making block DCSN is triggered by the rising edge of PWR_ON. It updates J_ENCODE[4:0] based on the comparison result of M1 vs. 130. This pulls the VCO frequency close to the target frequency.

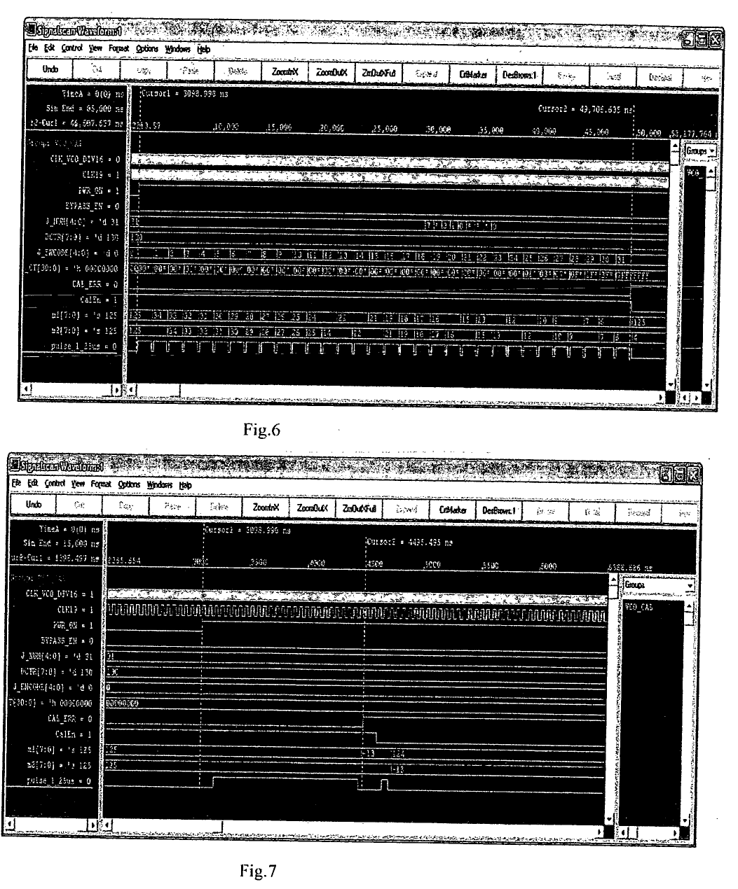

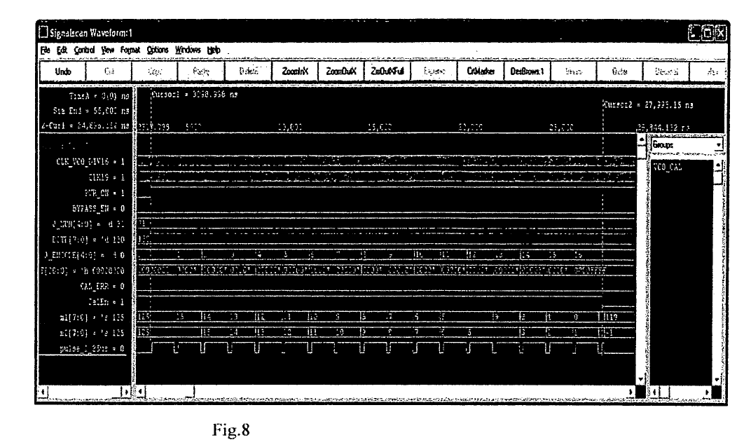

The calibration algorithm described above has been implemented in a verilog code. Simulation results based on verilog code are shown through FIG. 6 to FIG. 9. FIG. 6 shows the case where VCO is too slow. DCSN sweeps full range of J_ENCODE[4:0] from 0 to 31 but still is unable to speed up the VCO frequency to the desired frequency. After the J_ENCODE[4:0] sweeps in the highest value, CAL_ERR rises to high indicating a failure in calibration. CalEn goes to low to turn off calibration portion and switch the loop back to analog mode. This case also shows the maximum calibration time is less than 50 us. FIG. 7 shows the case where VCO is too fast. DCSN sets J_ENCODE[4:0] to decimal 0 but still cannot slow down the VCO to the wanted frequency. DCSN writes CAL_ERR to high and CalEn to low after calibration fails. FIG. 8 shows the case where VCO center frequency is at 1.668 GHz. DCSN finds the right J_ENCODE[4:0] in the middle of sweeping J_ENCODE. DCSN writes CalEn to low after finishing the calibration.

We have invented a VCO calibration algorithm, which trims the VCO center frequency to the wanted value. This technique demonstrates that it works with an 800 kHz clock divided from CLK19 reference. The total time required for the calibration is less than 50 us. CalEn is raised to indicate the finish of calibration. CAL_ERR is raised to indicate an error. In measurement, the nominal calibration time is 8 to 10 uS. This shows a much faster speed than previous work which generally requires more than 80 uS.

While the preferred embodiment of the invention has been described, it will be apparent to those skilled in the art that various modifications may be made in the embodiment without departing from the spirit of the present invention. Such modifications are all within the scope of this invention.

1. A frequency synthesizer to lock the voltage controlled oscillator (VCO) with a reference frequency, comprising:
a reference frequency;
a phase detector;
a low pass filter to filter out any ac component from said phase detector and to derive a dc control voltage; and
a voltage controlled oscillator, whose frequency is divided by a divider to compare with said reference frequency and is controlled by said dc control voltage, which is applied in two sequential modes: a calibration mode and an analog mode,
wherein said calibration mode locks coarsely said VCO into limited number of discrete frequency steps within a predetermined frequency tolerance of the reference frequency by resetting and holding a coarse calibrated dc control voltage in a coarse digital phase-locked loop, with a calibration clock frequency divided from said frequency of said VCO, and
wherein said analog mode starts with said coarse calibrated dc control voltage, reset and held during the calibration mode, for fine adjustment of said VCO frequency to lock with said reference frequency in a fine phase-locked loop.

2. The frequency synthesizer as described in claim 1, wherein the calibration clock frequency of the digital phase-locked loop is divided from the VCO frequency by a number no higher than the number of said discrete frequency steps.

3. The frequency synthesizer as described in claim 2, wherein the clock frequency of the digital phase-locked loop during the calibration mode divides the VCO frequency by a one half of the number of said discrete frequency steps.

4. The frequency synthesizer as described in claim 1, wherein:
said phase detector for the analog mode comprises a phase comparator and a charge pump, and
said phase detector for said calibration mode comprises a stepper to reset said coarse calibrated dc control voltage into a predetermined number of steps and is disabled to switched to said analog mode when the dc control voltage locks the VCO frequency within a preset tolerance of said reference frequency.

5. The frequency synthesizer as described in claim 4, wherein said stepper comprises a clock, a counter, and a decision-making block to incrementally step-change said coarse calibrated dc control voltage.

6. The frequency synthesizer as described in claim 5, wherein the number of steps is a binary-weighted number.

7. The frequency synthesizer as described in claim 6, wherein said decision-making block is a control unit that selects between enabling and disabling the counter, calculates the value of the VCO dc control voltage, and selects between breaking and reconnecting the PLL for the calibration mode.

8. The frequency synthesizer as described in claim 6, wherein said counter and said decision-making block are finite state machines.
